(19) United States
(12) Patent Application Publication
(10) Pub. No.: US 2014/0303920 A1
(43) Pub. Date: Oct. 9, 2014

(54) SYSTEM AND METHOD FOR ELECTROSTATIC DISCHARGE TESTING

(71) Applicant: HON HAI PRECISION INDUSTRY CO., LTD., New Taipei (TW)

(72) Inventors: WEI-CHIEH CHOU, New Taipei (TW); YING-TSO LAI, New Taipei (TW); EN-SHUO CHANG, New Taipei (TW); CHUN-JEN CHEN, New Taipei (TW)

(73) Assignee: HON HAI PRECISION INDUSTRY CO., LTD., New Taipei (TW)

(21) Appl. No.: 14/230,102

(22) Filed: Mar. 31, 2014

(30) Foreign Application Priority Data
Apr. 8, 2013 (TW) 102112419

(51) Int. Cl. G01R 31/28

(52) U.S. Cl. CPC G01R 31/2815
USPC 702/82

(57) ABSTRACT

A system and a method for ESD testing are contained in an ESD testing system which is running on an electronic device. A storage unit of the electronic device pre-stores a layout file which includes a layout pattern having electrical traces, an ESD entry point, and mounted positions of multiple electronic elements. The ESD testing method obtains the layout file from the storage unit; displays the layout pattern on a display unit of the electronic device, simulates ESD in the ESD entry point of the displayed layout pattern, tests electrical characteristics of the electrical traces between the ESD entry point and the mounted positions of multiple electronic elements to determine whether the electrical characteristics of the electrical traces pass or fail the ESD test, and marks the electrical traces which fail the ESD test on the displayed layout pattern.

The present disclosure relates to electro-static discharge (ESD) testing, and particularly to a system and a method for ESD testing.

### BACKGROUND

Existing electronic devices, such as computers usually have several ports, such as USB ports, and most of these electronic devices are provided with hot-swap function. However, the hardware and software systems of these electronic devices may easily be damaged by ESD caused by hot-swap events acting on these electronic devices, which will bring system crashes or data loss. Therefore, these electronic devices must be tested for ESD during production, in order to avoid system failures caused by ESD.

In an existing ESD test, testers make ESD tests on the printed circuit board assembly (PCBA) of the electronic device after layouts of their printed circuit boards (PCBs) are completed. Where the PCBAs fail the ESD tests, multiple electronic components may be damaged, testers need to find out the damaged electronic components, and modify the layouts of the PCBs. However, it will increase the cost of production and waste a lot of time to find out the damaged electronic components, and testers need to repeatedly test the modified layouts of these PCBs.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic diagram of an embodiment of an ESD testing system.

FIG. 2 is a block diagram of the ESD testing system of FIG. 1.

FIG. 3 is a flowchart illustrating an ESD testing method.

### DETAILED DESCRIPTION

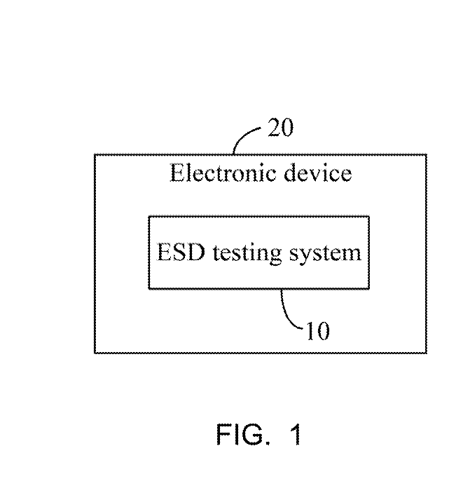

FIG. 1 shows an ESD testing system 10 running on an electronic device 20. The electronic device 20 may be a computer or a server. In other embodiments, the ESD testing system 10 is a hardware unit on the electronic device 20.

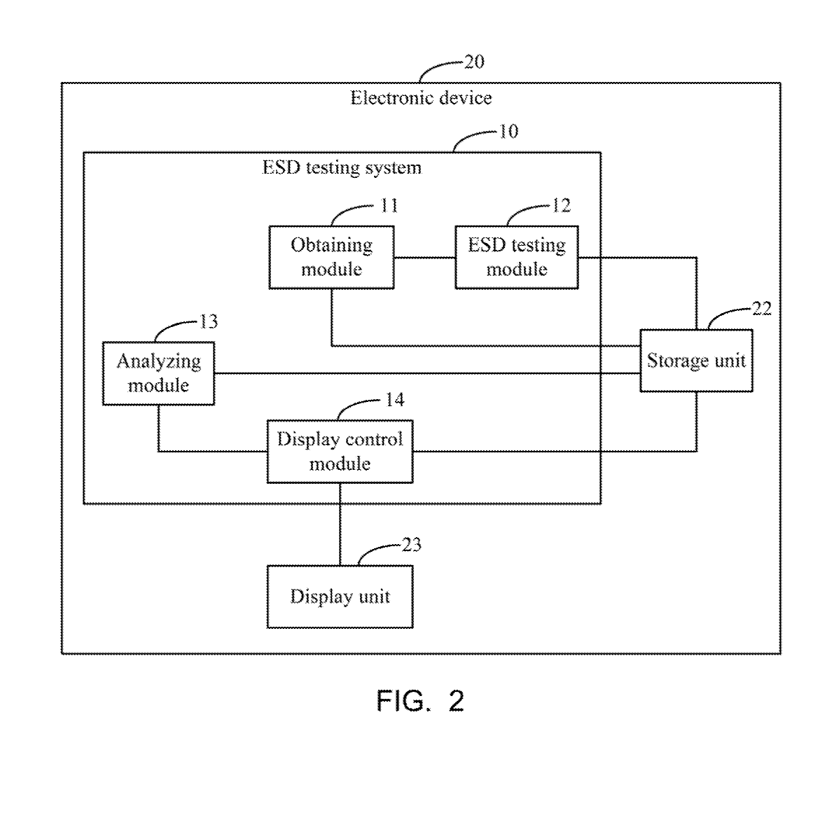

FIG. 2 shows that the ESD testing system 10 is also connected to a storage unit 22 and a display unit 23 of the electronic device 20. In an embodiment, the storage unit 22 pre-stores a layout file of a printed circuit board (PCB). In an embodiment, the layout file includes a layout pattern having electrical traces, an ESD entry point, and mounted positions of multiple electronic elements.

The ESD system 10 includes an obtaining module 11 and a display control module 14. The obtaining module 11 obtains the layout file from the storage unit 22, and the display control module 14 displays the layout pattern on the display unit 23 according to the obtained layout file.

The ESD system 10 further includes an ESD testing module 12 and an analyzing module 13. The ESD testing module 12 simulates ESD in the ESD entry point of the displayed layout pattern, tests electrical characteristics of the electrical traces between the ESD entry point and the mounted positions of multiple electronic elements, and stores a test result in the storage unit 22.

The analyzing module 13 obtains the test result from the storage unit 22 for analyzing and determines whether the electrical characteristics of the electrical traces pass or fail the ESD test.

In one embodiment, the analyzing module 13 compares the electrical characteristics of the electrical traces with predetermined parameters, to determine whether the electrical characteristics of the electrical traces pass or fail the ESD test. In one embodiment, the electrical characteristics may be selected from a group consisting of the widths, the capacitance, and the impedance of the electrical traces.

In one embodiment, the display control module 14 marks the electrical traces which fail the ESD test on the displayed layout pattern.

Therefore, tester can quickly locate electrical traces which fail the ESD test, and modify the marked electrical traces. After the marked electrical traces are modified, testers can run the ESD testing system 10 on the electronic device 20 to test the modified layout file again, until all the electrical traces pass the ESD test.

Therefore, the test efficiency is greatly improved, and the damage rate of the electronic components will be greatly reduced compared to the ESD tests being physically carried on a PCBA.

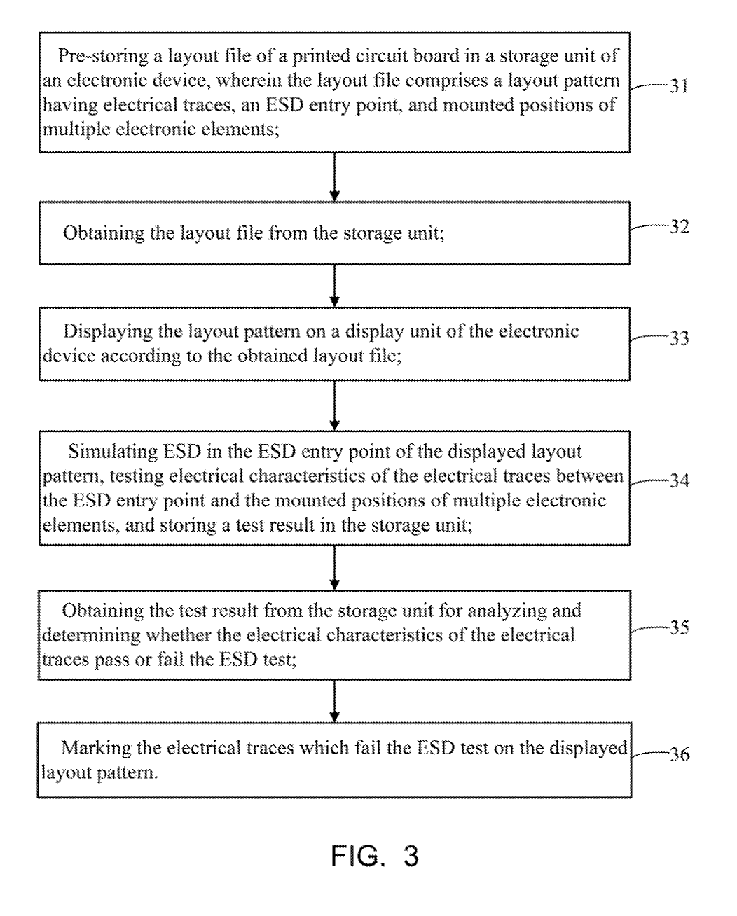

FIG. 3 is a flowchart illustrating an ESD testing method.

In 31, the storage unit re-stores a layout file of a PCB.

In one embodiment, the layout file includes a layout pattern having electrical traces, an ESD entry point, and mounted positions of multiple electronic elements.

In 32, the obtaining module obtains the layout file from the storage unit 22.

In 33, the display control module displays the layout pattern on the display unit according to the obtained layout file.

In 34, the ESD testing module simulates ESD in the ESD entry point of the displayed layout pattern, tests electrical characteristics of the electrical traces between the ESD entry point and the mounted positions of multiple electronic elements, and stores a test result in the storage unit.

In 35, the analyzing module obtains the test result from the storage unit for analyzing and determines whether the electrical characteristics of the electrical traces pass or fail the ESD test.

In 36, the display control module marks the electrical traces which fail the ESD test on the displayed layout pattern.

It is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. An ESD testing system running on an electronic device, the system comprising:
an obtaining module configured to obtain a layout file of a printed circuit board pre-stored in a storage unit of the electronic device, wherein the layout file comprises a layout pattern having electrical traces, an ESD entry point, and mounted positions of multiple electronic elements;
a display control module configured to display the layout pattern on a display unit of the electronic device according to the obtained layout file;
an ESD testing module configured to simulate ESD in the ESD entry point of the displayed layout pattern, test electrical characteristics of the electrical traces between the ESD entry point and the mounted positions of multiple electronic elements, and store a test result in the storage unit; and
an analyzing module configured to obtain the test result from the storage unit for analyzing and determine whether the electrical characteristics of the electrical traces pass or fail the ESD test, wherein the display control module is further configured to mark the electrical traces which fail the ESD test on the displayed layout pattern.

2. The system as described in claim 1, wherein the analyzing module compares the electrical characteristics of the electrical traces with predetermined parameters, to determine whether the electrical characteristics of the electrical traces pass or fail the ESD test.

3. The system as described in claim 2, wherein the electrical characteristics are selected from a group consisting of the widths, the capacitance, and the impedance of the electrical traces.

4. An ESD testing method comprising:
pre-storing a layout file of a printed circuit board in a storage unit of an electronic device, wherein the layout file comprises a layout pattern having electrical traces, an ESD entry point, and mounted positions of multiple electronic elements;
obtaining the layout file from the storage unit;
displaying the layout pattern on a display unit of the electronic device according to the obtained layout file;
simulating ESD in the ESD entry point of the displayed layout pattern, testing electrical characteristics of the electrical traces between the ESD entry point and the mounted positions of multiple electronic elements, and storing a test result in the storage unit;
obtaining the test result from the storage unit for analyzing and determining whether the electrical characteristics of the electrical traces pass or fail the ESD test;
marking the electrical traces which fail the ESD test on the displayed layout pattern.

5. The method as described in claim 4, the electrical characteristics of the electrical traces are compared with predetermined parameters, to determine whether the electrical characteristics of the electrical traces pass the ESD test.

6. The method as described in claim 5, wherein the electrical characteristics are selected from a group consisting of the widths, the capacitance, and the impedance of the electrical traces.
